(19) United States
(12) Patent Application Publication
(10) Pub. No.: US 2005/0106835 A1
(43) Pub. Date: May 19, 2005

(54) Trench isolation structure and method of manufacture therefor

(75) Inventors: Nace Layadi, Singapore (SG); Alvaro Maury, Villa des Flores (SG)

Correspondence Address: HITT GAINES, PC;AGERE SYSTEMS INC., PO BOX 832570, RICHARDSON, TX, 75083, US

(73) Assignee: Agere Systems Inc., Allentown, PA (US)

(21) Appl. No.: 10/716,278

(22) Filed: Nov. 18, 2003

(51) Int. Cl. H01L 21/76

(52) U.S. Cl. 438/424

(57) ABSTRACT

The present invention provides a trench isolation structure, a method for manufacturing a trench isolation structure, and a method for manufacturing an integrated circuit including the trench isolation structure. The trench isolation structure, in accordance with the principles of the present invention, may include a substrate having a trench located therein, and an isolation material located within the trench, wherein the isolation material has no undercut at corners where the isolation material meets the substrate.

### TECHNICAL FIELD OF THE INVENTION

The present invention is directed, in general, to isolation structures for an integrated circuit and, more specifically, to a trench isolation structure, a method of manufacture therefor, and a method of manufacturing an integrated circuit including the trench isolation structure.

### BACKGROUND OF THE INVENTION

Integrated circuits are now well known and extensively used in various technologies. Over the last decade, the operating speeds and packing densities have increased substantially while the device size has been dramatically reduced. The combination of increased packing density and device size reduction have posed ever new problems for the semiconductor fabrication industry that have not previously been of concern. One such area of fabrication involves the formation of isolation structures located on the semiconductor wafer substrate, between transistor devices, to provide electrical isolation between the devices. A variety of techniques, generally termed isolation processes, have been developed to isolate such devices in integrated circuits.

One such process is local oxidation of silicon (LOCOS), in which a silicon nitride (Si₃N₄) film is used to isolate selected regions of the semiconductor substrate in which field oxide structures are formed. This isolation technique has been widely used as an isolation technique of very large-scale integrated (VLSI) circuits. While this technique has been quite useful and extensively used in larger submicron devices, its use in smaller, present day submicron technologies has encountered limitations due to the increased packing density.

To overcome the limitations associated with the LOCOS process, the industry devised an alternative isolation process known as shallow trench isolation (STI). This particular process provides an isolation structure that requires less surface area on the semiconductor substrate. However, even this process has encountered limitations in view of the increased packing density.

One problem currently encountered in today's STI structures is oxide undercut at the corners where the STI oxide meets the substrate. This undercut tends to create a high dielectric field at the corners, resulting in leakage current issues in the device. Another issue created by the oxide undercut (“divot”) is formation of residual polysilicon that may create undesirable leakage. The residual polysilicon may be formed on the undercut or divot after the gate etch.

The oxide undercut occurs, whether admitted to or not, when a silicon-nitride mask is used to form the trench the STI structure is ultimately formed within. Unfortunately, silicon-nitride masks are the most prevalent hardmask for forming trenches in semiconductor substrates.

Accordingly, what is needed in the art is a trench isolation structure that does not experience the undercutting issues experienced by the prior art structures.

### SUMMARY OF THE INVENTION

To address the above-discussed deficiencies of the prior art, the present invention provides a trench isolation structure, a method for manufacturing a trench isolation structure, and a method for manufacturing an integrated circuit including the trench isolation structure. The trench isolation structure, in accordance with the principles of the present invention, may include a substrate having a trench located therein, and an isolation material located within the trench, wherein the isolation material has no undercut at corners where the isolation material meets the substrate.

The method for manufacturing the trench isolation structure, as covered by the present invention, may include the steps of forming a polysilicon hardmask over a substrate, etching a trench in the substrate through the polysilicon hardmask, and filling the trench with an insulative material. The method for manufacturing the integrated circuit is similar to the method for forming the trench isolation structure, however, it may also include the steps of forming transistor devices over the substrate, and constructing an interlevel dielectric layer over the transistor devices and having interconnects located therein, wherein the interconnects contact the transistor devices to form an operational integrated circuit.

The foregoing has outlined preferred and alternative features of the present invention so that those skilled in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the spirit and scope of the invention.

### BRIEF DESCRIPTION OF THE DRAWINGS

The invention is best understood from the following detailed description when read with the accompanying FIGUREs. It is emphasized that in accordance with the standard practice in the semiconductor industry, various features are not drawn to scale. In fact, the dimensions of the various features may be arbitrarily increased or reduced for clarity of discussion. Reference is now made to the following descriptions taken in conjunction with the accompanying drawings, in which:

FIG. 1 illustrates a cross-sectional view of one embodiment of a semiconductor device constructed according to the principles of the present invention;

FIG. 2 illustrates a cross-sectional view of a partially completed semiconductor device;

FIG. 3 illustrates a cross-sectional view of the partially completed semiconductor device illustrated in FIG. 2 after patterning a pad oxide and polysilicon hardmask, and thereafter forming trenches within a substrate through the polysilicon hardmask;

FIG. 4 illustrates a cross-sectional view of the partially completed semiconductor device illustrated in FIG. 3 after forming a liner oxide within the trenches;

FIG. 5 illustrates a cross-sectional view of the partially completed semiconductor device illustrated in FIG. 4 after a layer of an insulative material has been formed over and within the trenches;

FIG. 6 illustrates a cross-sectional view of the partially completed semiconductor device illustrated in FIG. 5 after a conventional removal process, such as a conventional chemical-mechanical-polishing (CMP) process;

FIG. 7 illustrates a cross-sectional view of the partially completed semiconductor device illustrated in FIG. 6 after removal of the remaining polysilicon hardmask and pad oxide, thus completing the isolation structures; and

FIG. 8 illustrates a cross-sectional view of a conventional integrated circuit (IC) incorporating semiconductor devices constructed according to the principles of the present invention.

### DETAILED DESCRIPTION

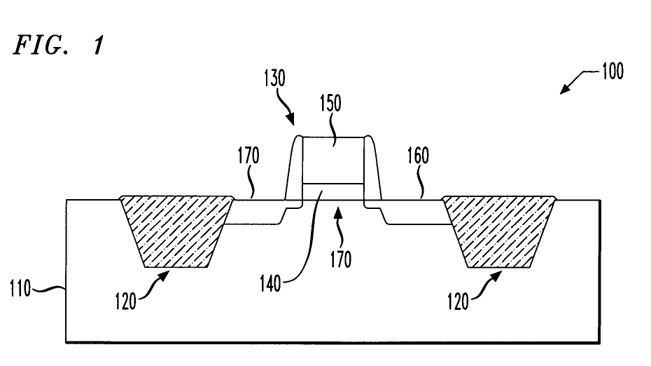

Referring initially to FIG. 1, illustrated is a cross-sectional view of one embodiment of a semiconductor device 100 constructed according to the principles of the present invention. In the embodiment illustrated in FIG. 1, the semiconductor device 100 includes a substrate 110. Located within the substrate 110 in the embodiment of FIG. 1 are isolation structures 120.

In this particular embodiment the isolation structures 120 are shallow trench isolation (STI) structures, however, it should be noted that other isolation structures are within the broad scope of the present invention. These particular isolation structures 120, in contrast to those of the prior art, have no undercut at the upper corners where the isolation material of the isolation structures 120 meet the substrate 110. Fortunately, as compared to the prior art structures, the semiconductor device 100 experiences reduced, and optimally little or no leakage current at these corners.

Located between the isolation structures 120 in the embodiment of FIG. 1 is a conventional transistor 130. The conventional transistor 130 includes a conventional gate oxide 140 and a conventional gate electrode 150. The conventional transistor 130 further includes conventional source/drain regions 160 located between a channel region 170, which is positioned below the gate oxide 140, and the isolation structures 120.

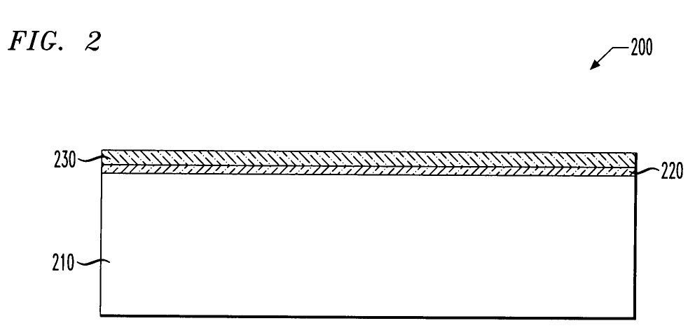

Turning now to FIGS. 2-7, illustrated are cross-sectional views of detailed manufacturing steps instructing how one might, in an advantageous embodiment, manufacture a semiconductor device similar to the semiconductor device 100 depicted in FIG. 1. FIG. 2 illustrates a cross-sectional view of a partially completed semiconductor device 200. The partially completed semiconductor device 200 includes a substrate 210. The substrate 210 may, in an exemplary embodiment, be any layer located in the partially completed semiconductor device 200, including a wafer itself or a layer located above the wafer (e.g., epitaxial layer). In the embodiment illustrated in FIG. 2, the substrate 210 is a P-type semiconductor substrate; however, one skilled in the art understands that the substrate 210 could be an N-type substrate without departing from the scope of the present invention.

Located over the substrate 210 in the embodiment shown in FIG. 2 is a pad oxide 220. The pad oxide 220 is a conventional structure often formed between the substrate 210 and a later formed hardmask layer. In the embodiment of FIGS. 2-7, the pad oxide 220 is a thin oxide layer having a thickness ranging from about 10 nm to about 20 nm. While the pad oxide 220 is generally grown, certain embodiments might exist where the pad oxide 220 is deposited.

Located over the pad oxide 220 is an oxidizable hardmask 230. One particularly useful oxidizable hardmask is undoped polysilicon. Even though the oxidizable hardmask 230 will be referred to as a polysilicon hardmask 230 for the remainder of the document, the present invention is not limited to such. For example, other oxidizable materials that are capable of performing as a hardmask could easily be used, and may or may not, depending on the rate and temperature that they oxidize, work equally as well.

The polysilicon hardmask 230 in the exemplary embodiment of FIG. 2 has been formed over the pad oxide 220 using conventional processes. For example, a conventional chemical vapor deposition (CVD) process, or another similar process could be used to form the polysilicon hardmask 230. In one exemplary embodiment the polysilicon hardmask 230 is formed having a thickness ranging from about 100 nm to about 200 nm. Other thicknesses, depending on the design, work just as well. Thus, the present invention should not be limited to the aforementioned polysilicon hardmask 230 thicknesses.

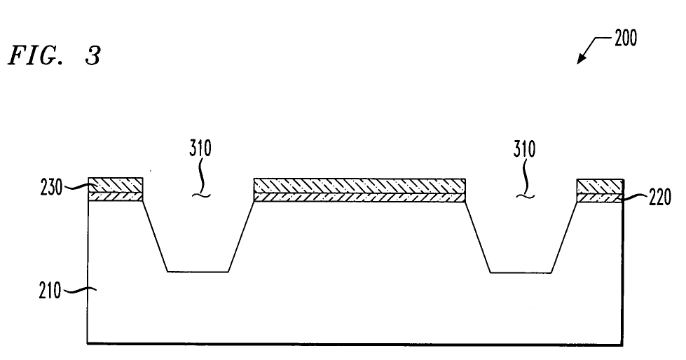

Turning now to FIG. 3, illustrated is a cross-sectional view of the partially completed semiconductor device 200 illustrated in FIG. 2 after patterning the pad oxide 220 and polysilicon hardmask 230, and thereafter forming trenches 310 within the substrate 210 through the polysilicon hardmask 230. Those skilled in the art understand the procedures required to pattern the pad oxide 220 and polysilicon hardmask 230, as well as form the trenches 310. Therefore, details of these processes may be foregone.

The trenches 310, which in the embodiment of FIG. 3 are shallow trenches, typically have a depth of about 0.1 μm to about 0.5 μm below the upper surface of the substrate 210. Similarly, the trenches 310 typically have widths at their opening ranging from about 0.15 μm to about 20 μm. Other depths and widths could, however, conceivably be used in conjunction with the present invention.

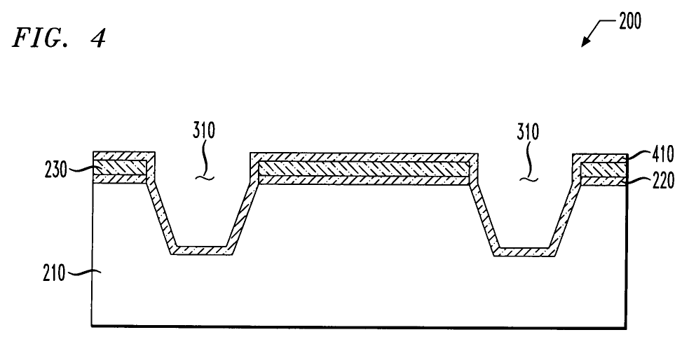

Turning now to FIG. 4, illustrated is a cross-sectional view of the partially completed semiconductor device 200 illustrated in FIG. 3 after forming a liner oxide 410 within the trenches 310. The liner oxide 410 is typically grown using a conventional dry or wet oxidation process, but should not be limited to such processes. The liner oxide 410, as compared to the liner oxides of the prior art devices, also forms along the sides and top of the polysilicon hardmask 230. It is this unique feature, which is a result of the polysilicon hardmask 230 being oxidizable, that provides for substantially no undercutting in the final device. The thickness of the liner oxide 410 may vary, however, it is often the case that the liner oxide 410 has a thickness ranging from about 10 nm to about 20 nm.

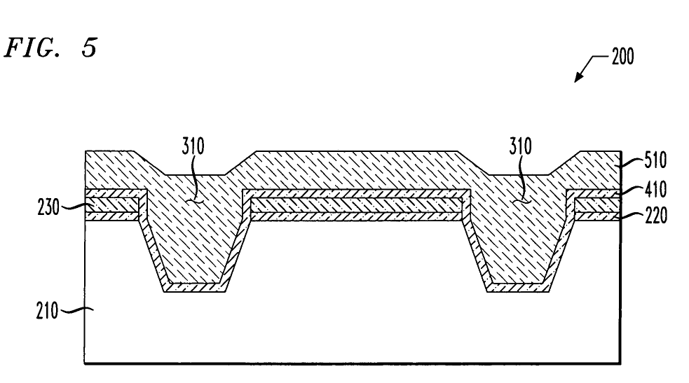

Turning now to FIG. 5, illustrated is a cross-sectional view of the partially completed semiconductor device 200 illustrated in FIG. 4 after a layer of an insulative material 510 has been formed over and within the trenches 310. This insulative material 510, as shown, may completely fill the trenches 310 in a conformal fashion. The insulative material 510, which may comprise an oxide or another similar material, provides the requisite isolation for the semiconductor device 200.

While the liner oxide 410 was preferably grown within the trenches 310 and along the sides and top of the polysilicon hardmask 230, the insulative material 510 is preferably deposited. Those skilled in the art understand the many ways with which the insulative material 510 could be deposited.

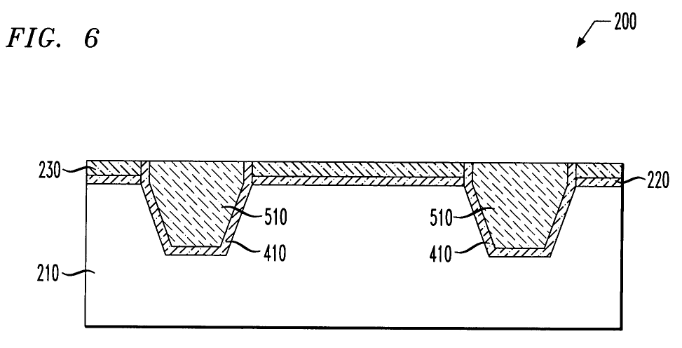

Turning now to FIG. 6, illustrated is a cross-sectional view of the partially completed semiconductor device 200 illustrated in FIG. 5 after a conventional removal process, such as a conventional chemical-mechanical-polishing (CMP) process. As is shown, the CMP process removes the excess insulative material 510 and remaining liner oxide 410 from the top portion of the polysilicon hardmask 230. The CMP process may use a timed endpoint, or alternatively some sort of endpoint detection means, to determine when to stop. It is important, however, that the removal process does not over polish the insulative material 510.

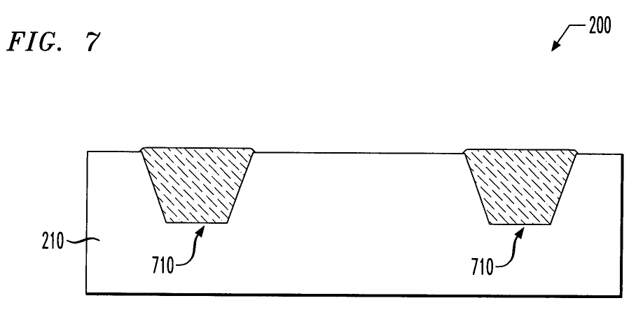

Turning now to FIG. 7, illustrated is a cross-sectional view of the partially completed semiconductor device 200 illustrated in FIG. 6 after removal of the remaining polysilicon hardmask 230 and pad oxide 220, thus completing the isolation structures 710. A number of different selective removal processes could be used to remove the remaining polysilicon hardmask 230, however, two exemplary techniques include a wet chemical etch and a plasma etch. The wet chemical etch could use a compound, such as HCl, that has an etch selectivity that favors polysilicon and disfavors oxides. Other compounds that have a selectivity that favors polysilicon could also be used. If the plasm etch were used, a compound such as HCl, HBr, or any other similar compound, could be used.

Ultimately what results are the isolation structures 710 that have substantially no undercut at the upper corners where the insulative material of the isolation structures 710 meet the substrate 210. As previously mentioned, this prevents a high dielectric field from occurring at these points, and thus substantially reduces the amount of leakage current that results. After the completion of the isolation structures 710 of FIG. 7, the manufacturing process would continue, resulting in a completed semiconductor device, similar to the completed semiconductor device 100 illustrated in FIG. 1.

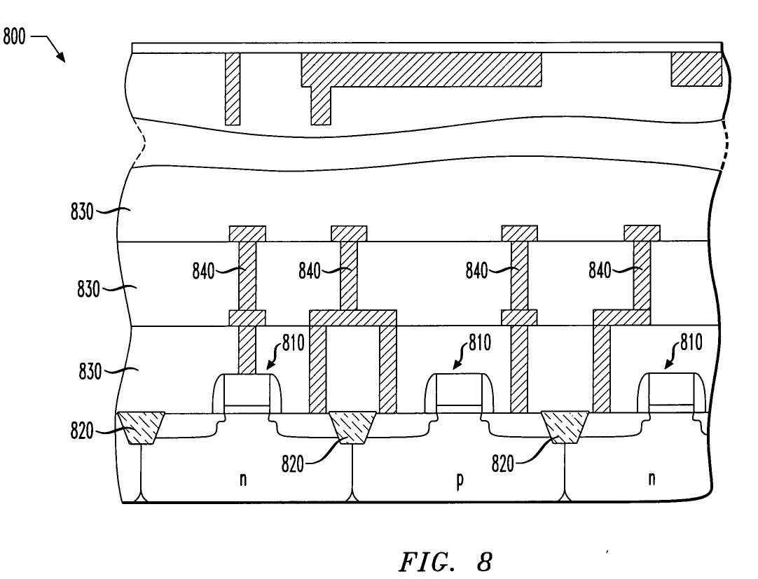

Referring finally to FIG. 8, illustrated is a cross-sectional view of a conventional integrated circuit (IC) 800 incorporating semiconductor devices 810 constructed according to the principles of the present invention. The IC 800 may include devices, such as transistors used to form CMOS devices, BiCMOS devices, Bipolar devices, or other types of devices. The IC 800 may further include passive devices, such as inductors or resistors, or it may also include optical devices or optoelectronic devices. Those skilled in the art are familiar with these various types of devices and their manufacture. In the particular embodiment illustrated in FIG. 8, the IC 800 includes the semiconductor devices 810 located between isolation structures 820. The IC 800 of FIG. 8 further includes dielectric layers 830 located over the semiconductor devices 810. Additionally, interconnect structures 840 are located within the dielectric layers 830 to interconnect various devices, thus, forming the operational IC 800.

Although the present invention has been described in detail, those skilled in the art should understand that they can make various changes, substitutions and alterations herein without departing from the spirit and scope of the invention in its broadest form.

1. A method for manufacturing a trench isolation structure, comprising:
forming a polysilicon hardmask over a substrate;
etching a trench in said substrate through said polysilicon hardmask; and
filling said trench with an insulative material.

2. The method as recited in claim 1 further including placing a pad oxide layer between said substrate and said polysilicon hardmask.

3. The method as recited in claim 2 wherein said pad oxide layer has a thickness ranging from about 10 nm to about 20 nm.

4. The method as recited in claim 1 further including growing a liner oxide within said trench and over said polysilicon hardmask prior to filling said trench with said insulative material.

5. The method as recited in claim 4 wherein said grown liner oxide has a thickness ranging from about 10 nm to about 20 nm.

6. The method as recited in claim 1 wherein filling said trench with an insulative material includes depositing said insulative material within said trench.

7. The method as recited in claim 1 wherein said polysilicon hardmask has a thickness ranging from about 100 nm to about 200 nm.

8. The method as recited in claim 1 wherein said trench has a width ranging from about 0.15 μm to about 20 μm and has a depth ranging from about 0.1 μm to about 0.5 μm.

9. A trench isolation structure formed using said method of claim 1.

10. A method for manufacturing an integrated circuit, comprising:
forming trench isolation structures in a substrate, including;
forming a polysilicon hardmask over said substrate;
etching a trench in said substrate through said polysilicon hardmask; and
filling said trench with an insulative material;
forming transistor devices over said substrate; and
constructing an interlevel dielectric layer over said transistor devices and having interconnects located therein, wherein said interconnects contact said transistor devices to form an operational integrated circuit.

11. The method as recited in claim 10 further including placing a pad oxide layer between said substrate and said polysilicon hardmask.

12. The method as recited in claim 11 wherein said pad oxide layer has a thickness ranging from about 10 nm to about 20 nm.

13. The method as recited in claim 10 further including growing a liner oxide within said trench and over said polysilicon hardmask prior to filling said trench with said insulative material.

14. The method as recited in claim 13 wherein said grown liner oxide has a thickness ranging from about 10 nm to about 20 nm.

15. The method as recited in claim 10 wherein filling said trench with an insulative material includes depositing said insulative material within said trench.

16. The method as recited in claim 10 wherein said polysilicon hardmask has a thickness ranging from about 100 nm to about 200 nm.

17. The method as recited in claim 10 wherein said trench has a width ranging from about 0.15 μm to about 20 μm and has a depth ranging from about 0.1 μm to about 0.5 μm.

18. An integrated circuit formed using said method of claim 10.

19. A trench isolation structure, comprising:
a substrate having a trench located therein;
an isolation material located within said trench, wherein said isolation material has no undercut at corners where said isolation material meets said substrate.

20. The trench isolation structure as recited in claim 19 further including a liner oxide located between said trench and said isolation material.
